(19) United States
(12) Patent Application Publication
(10) Pub. No.: US 2017/0110323 A1
(43) Pub. Date: Apr. 20, 2017

(54) METHOD OF FORMING PATTERNED METAL FILM LAYER AND PREPARATION METHOD OF TRANSISTOR AND ARRAY SUBSTRATE

(71) Applicants: BOE TECHNOLOGY GROUP CO., LTD., Beijing (CN); HEFEI BOE OPTOELECTRONICS TECHNOLOGY CO., LTD., Heifei (CN)

(72) Inventors: Hui An, Beijing (CN); Biliang Dong, Beijing (CN)

(21) Appl. No.: 15/229,477

(22) Filed: Aug. 5, 2016

(30) Foreign Application Priority Data
Oct. 15, 2015 (CN) 201510667132.4

(51) Int. Cl. H01L 21/283; H01L 29/45; H01L 29/417; H01L 21/027; H01L 29/40; H01L 29/423

(52) U.S. Cl. CPC H01L 21/283; H01L 29/401; H01L 29/42384; H01L 29/41733; H01L 21/0273; H01L 29/45

(57) ABSTRACT

A method of forming a patterned metal film layer and preparation methods of a transistor and an array substrate are disclosed, in the technical field of displays. The method of forming a patterned metal film layer of the invention comprises: sequentially depositing a sacrificial layer and a photoresist layer on a substrate, and forming a patterned sacrificial layer and a patterned photoresist layer overlying on the patterned sacrificial layer by exposure, development, and etching, wherein a side wall of the patterned sacrificial layer adjacent to a patterned metal film layer to be formed forms a chamfer; depositing a metal film layer on the substrate after finishing the above step, and removing the patterned photoresist layer and the sacrificial layer to form a patterned metal film layer.

### TECHNICAL FIELD

The invention belongs to the technical field of display, and provides a method of forming a patterned metal film layer and preparation methods of a thin film transistor and an array substrate.

### BACKGROUND ART

At present, commonly-used flat panel display apparatuses include liquid crystal displays (simply referred to as LCD) and OLED (organic light-emitting diode) displays. Either a liquid crystal display or an OLED display comprises an array substrate, in which a plurality of thin film transistors (simply referred to as TFT) are provided. The thin film transistor comprises three electrodes, which are a gate electrode, a source electrode, and a drain electrode.

With continuous update of design processes and production techniques of semiconductors as well as the improvement of the speed of elements themselves and the increase of size and resolution of display panels, the influence of the time delay of resistance-capacitance signals (RC time delay) is more and more significant. This requires that a metal material with a relatively low resistance is used to form an electrode or a lead wire. At present, the metal material often used is aluminum (Al). Due to poor thermal stability of pure aluminum thin film, serious hillock defect are prone to generate on its surface in the process of high-temperature treatment. In practical use, the defect of short circuit between the gate electrode and the drain electrode or between the drain electrode and the lead wire thereof will be caused by the hillock defect. Aluminum alloy materials may be used instead of pure aluminum materials. For example, materials such as Al—Nd, Al—Ce, Al—Nd—Mo, etc., are used to form electrodes or lead wires. However, when forming an electrode or a lead wire with the materials described above, the resistance of the electrode or the lead wire is increased while the occurrence of hillock defect is reduced.

The resistivity of pure aluminum is typically 2.66 μΩ.cm. With the requirements of larger area, high-speed drive, and high fineness (4K*2K) of display products, copper with a lower resistivity (Cu with a resistivity of 1.67 μΩ.cm) are gradually attractive. However, when metal copper is used as an electrode or a lead wire in the processing procedure of a TFT array, there is the following problem. In a conventional copper etching process, a solution such as hydrogen peroxide (H₂O₂), etc., is typically used to corrode a metal copper thin film, but a hydrogen peroxide solution has the risk of heat emission and explosion under the catalysis of concentrated metal ions. Therefore, how to prevent the occurrence of this kind of problem becomes a technical problem urgent to be solved.

As for methods for forming patterned metal film layers, the requirements for improvements still exist.

### SUMMARY OF THE INVENTION

One embodiment of the invention provides a method of forming a patterned metal film layer, comprising:

sequentially depositing a sacrificial layer and a photoresist layer on a substrate, and forming a patterned sacrificial layer and a patterned photoresist layer overlying on the patterned sacrificial layer by exposure, development, and etching, wherein a side wall of the patterned sacrificial layer adjacent to a patterned metal film layer to be formed forms a chamfer;

depositing a metal film layer on the substrate after finishing the above step, wherein the upper surface of the sacrificial layer is higher than the upper surface of a patterned metal film layer to be formed; and

removing the patterned photoresist layer and the sacrificial layer to form a patterned metal film layer.

Preferably, before the step of depositing a metal film layer, it further comprises:

a step of depositing an adhesion layer.

Further preferably, the material of the adhesion layer is titanium.

Preferably, the material of the sacrificial layer is aluminum oxide.

Preferably, the material of the metal film layer is copper.

Preferably, the material of the photoresist layer is a positive photoresist.

Preferably, the step of removing the patterned photoresist layer and the sacrificial layer to form a patterned metal film layer specifically comprises:

removing the patterned photoresist layer with a photoresist-removing liquid, and thus removing the metal film layer on the photoresist layer; and

removing the patterned sacrificial layer with acid to form a patterned metal film layer, wherein the acid does not corrode the substrate and the metal film layer.

Further preferably, the acid is phosphoric acid or hydrochloric acid.

Further preferably, ultrasonic treatment and oscillation are used as auxiliary means in the process of peeling.

Another embodiment of the invention provides a preparation method of a thin film transistor comprising a gate electrode, a source electrode, and a drain electrode, wherein the gate electrode and/or the source electrode and drain electrode are produced by using the method of forming a patterned metal film layer described above.

Still another embodiment of the invention provides a preparation method of an array substrate, comprising the preparation method of a thin film transistor described above.

### BRIEF DESCRIPTION OF THE DRAWINGS

FIG. 1 is a schematic diagram of forming a sacrificial layer in the method of forming a patterned metal film layer in Example 1 of the invention;

FIG. 2a is a schematic diagram of forming a patterned negative photoresist layer in the method of forming a patterned metal film layer in Example 1 of the invention;

FIG. 2b is a schematic diagram of forming a patterned positive photoresist layer in the method of forming a patterned metal film layer in Example 1 of the invention;

FIG. 3 is a schematic diagram of forming a patterned sacrificial layer in the method of forming a patterned metal film layer in Example 1 of the invention;

FIG. 4 is a schematic diagram of forming a metal film layer in the method of forming a patterned metal film layer in Example 1 of the invention;

FIG. 5 is a schematic diagram of removing the patterned photoresist layer in the method of forming a patterned metal film layer in Example 1 of the invention;

FIG. 6 is a schematic diagram of removing the patterned sacrificial layer to form a patterned metal film layer in the method of forming a patterned metal film layer in Example 1 of the invention;

FIG. 7 is a schematic diagram of the preparation method of a thin film transistor in Example 2 of the invention; and

FIG. 8 is a schematic diagram of the array substrate in Example 3 of the invention.

### DESCRIPTION OF EMBODIMENTS

In order to improve the preparation method of thin film transistors, embodiments of the invention provide preparation methods of forming a patterned metal film layer, a thin film transistor, and an array substrate, without steps of directly performing exposure, development, and etching on metal film layers, and without using the etching process wherein hydrogen peroxide is used. It prevents the problem that a hydrogen peroxide solution has the risk of heat emission and explosion under the catalysis of concentrated metal ions when the hydrogen peroxide solution is used to etch a metal film layer. In an embodiment of the invention, wet etching process is replaced by a lift-off technique using a special treatment of undercut of a sacrificial layer, such that the effect of peeling is better.

In order to allow the person skilled in the art to better understand the technical solution of the invention, the invention will be further described in detail in conjunction with accompanying drawings and specific embodiments.

### EXAMPLE 1

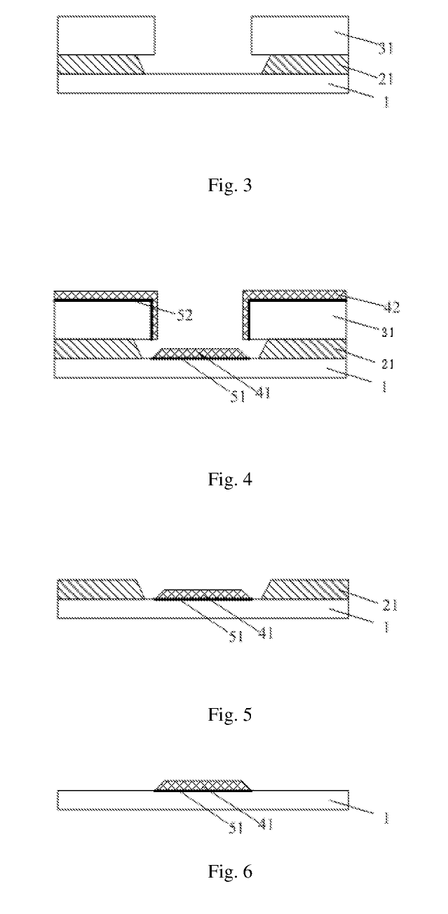

In conjunction with those shown in FIGS. 1, 2a, 2b, 3-6, this Example provides a method of forming a patterned metal film layer, comprising the following steps.

Step 1: as shown in FIGS. 1, 2a, 2b, 3, a sacrificial layer 2 and a photoresist layer 3 are sequentially deposited on a substrate 1, and a patterned sacrificial layer 21 and a patterned photoresist layer 31 overlying on the patterned sacrificial layer are formed by a normal photolithographic process, such as exposure, development, and etching, etc.; wherein a side wall of the patterned sacrificial layer 21 adjacent to a patterned metal film layer 41 to be formed forms a chamfer.

In this step, the substrate 1 is produced from transparent materials such as glass, etc., and is preliminarily cleaned. The sacrificial layer 2 is formed on the substrate 1 in a manner of physical vapor deposition (PVD); the photoresist layer 3 is then coated in a manner of roller coating, and the patterned sacrificial layer 21 and the patterned photoresist layer 31 overlying on the patterned sacrificial layer 21 are formed by removing a part of the sacrificial layer and the photoresist layer by exposure, development, and etching. Here, a side wall of the patterned sacrificial layer 21 adjacent to a patterned metal film layer 41 to be formed forms a chamfer, which means that the sacrificial layer is allowed to be over-etched at the edge position.

Here, the sacrificial layer 2 has a thickness which is higher than that of the metal film layer to be subsequently deposited, or, is higher than the total thickness of the metal film layer and an adhesion layer (if present), and can be corroded (sacrificed) by acid. The acid herein may corrode the sacrificial layer, but will not corrode the substrate material and the metal film. In view of the substrate that typically contains silicon, such as SiO, SiN, etc., the acid cannot be a fluorine-based acid such as hydrofluoric acid (HF). In addition, in order not to corrode common metal film layer materials such as copper, the acid is not an oxidizing acid such as nitrate, concentrated sulfuric acid, etc. A preferred non-oxidizing non-fluorine-based acid is phosphoric acid or hydrochloric acid. The material of the sacrificial layer is preferably aluminum oxide (Al₂O₃). Of course, another transparent insulating material may also be used as a bottom undercut processed patterned sacrificial layer 21 in the lift-off process, as long as it can be corroded by an acid which does not corrode the metal film and the substrate.

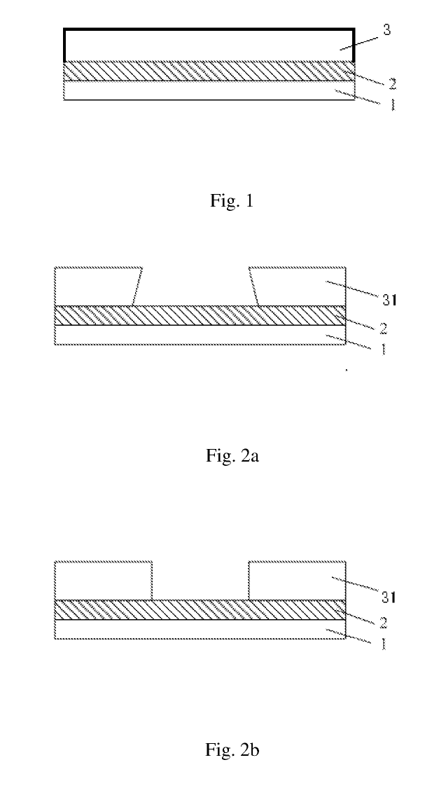

Here, it is to be understood in the art that with respect to a negative photoresist, the characteristic thereof is crosslinking occurring in the region irradiated by the UV (ultraviolet) light. As for the lift-off process, the thickness of step of the negative photoresist is much greater than the thickness of the target thin film. In this condition, UV light irradiation dose received by the top of the negative photoresist will be greater than that of the bottom of negative photoresist, such that the inverted trapezoidal morphology as shown in FIG. 2a will be very easily formed by methods such as adjusting the exposure dose, baking, etc., and it is very advantageous to the achievement of the peeling process. With respect to a positive photoresist, the characteristic thereof is on the contrary. Photochemical reaction occurs in the region irradiated by UV light, such that the positive photoresist in this region dissolves in a developing solvent and the morphology of the inverted trapezoidal step as shown in FIG. 2b cannot be formed. However, the positive photoresist has a higher resolution, which more complies with the development trend of gate line thinning in the future. The positive photoresist is preferably selected in this Example.

However, the method of this Example is still suitable for the peeling process of negative photoresists.

Step 2: as shown in FIGS. 4-6, adhesion layers 51 and 52 and metal film layers 41 and 42 are sequentially deposited on the substrate 1 after finishing the above step, and the patterned photoresist layer 31 (along with the adhesion layer 52 and the metal film layer 42 thereon) and the patterned sacrificial layer 21 are removed, to form a patterned adhesion layer 51 and a patterned metal film layer 41 (the patterned metal film layer 41 is fixed on the substrate 1 via the patterned adhesion layer 51).

Specifically, this step is to form adhesion layers 51 and 52 and metal film layers 41 and 42 in a manner of physical vapor deposition (PVD) or magnetron sputtering. The thickness of the sacrificial layer 2 is higher than the total thickness of the metal film layer 41 and the adhesion layer 51 and special undercut treatment is performed around the patterned sacrificial layer 21, such that the metal film layer 42 is disconnected from the patterned metal film layer 41 deposited on the substrate at the bottom of the patterned photoresist layer 31 after the metal film layer is deposited, and such that the photoresist-removing liquid may permeate from the boundary between the bottom of the patterned photoresist layer 31 and the place where the patterned sacrificial layer 21 is undercut. The photoresist-removing liquid used herein is an agent for removing the photoresist layer. Photoresist-removing liquids or strip solutions commonly used in the art include those commercially available. Acetone, absolute ethanol, etc., may also be used as the photoresist-removing liquid for peeling. The selection of the photoresist-removing liquid may be easily made by the person skilled in the art. The patterned photoresist layer is removed with a photoresist-removing liquid, and thus the metal film layer on the photoresist layer is removed (lift off) (FIG. 5). Subsequently, an acid such as a non-oxidizing non-fluorine-based acid, for example phosphoric acid or hydrochloric acid, is used to remove the patterned sacrificial layer, with only the patterned metal film layer left on the substrate (FIG. 6). Auxiliary means such ultrasonic treatment, oscillation, etc., may be added in the process of removing the patterned photoresist layer and the sacrificial layer, to increase the speed of the removing process and the effect of removing. The remaining metal film layer is the patterned metal film layer 41.

The reason for providing the sacrificial layer 2 with a certain thickness is as follows. If there is no sacrificial layer, the patterned metal film layers 41 and 42 may be connected together as an entirety and overlie on the surface of the patterned photoresist layer 31 with the whole surface thereof, resulting that the photoresist-removing liquid fails to effectively permeate the patterned metal film layer and preventing the patterned photoresist layer 31 from being dissolved by effective contact with the photoresist-removing liquid, such that the effect of peeling is very poor. Therefore, it is to be emphasized herein that the thickness of the sacrificial layer 21 should be greater than that of the metal film. The upper surface of the sacrificial layer 21 is higher than the upper surface of the metal film layer 41, and thus the chamfer structure formed also helps the profile of the patterned metal film layer 41 to form an inverted trapezoidal structure (i.e., narrow top and wide bottom), and this morphology has a better mechanical structure.

Here, the material of the metal film layer is preferably copper (Cu). Of course, the method described above is also suitable for the patterning of other metal film layers. The material of the adhesion layer 52 is preferably titanium (Ti).

It is to be indicated herein that the step of forming an adhesion layer in this Example may also be omitted. Of course, it is better to comprise this step so as to provide good fixation between the metal film layer and the substrate 1.

The method of forming a patterned metal film layer provided in this Example does not require the steps of performing exposure, development, and etching on metal film layers, and thus prevents the problem that a hydrogen peroxide solution has the risk of heat emission and explosion under the catalysis of concentrated metal ions when the hydrogen peroxide solution is used to etch a metal film layer. In this Example, wet etching process is replaced by a lift-off technique using a special treatment of undercut of a sacrificial layer, such that the effect of peeling is better.

### EXAMPLE 2

This Example provides a preparation method of a thin film transistor comprising a gate electrode, a source electrode, and a drain electrode, wherein the preparation of the gate electrode and/or the source electrode and the drain electrode are prepared by using the method in Example 1.

It can be understood by the person skilled in the art that the thin film transistor may be a top gate type thin film transistor or may be a bottom gate type thin film transistor. Here, significant difference between the top gate type thin film transistor and the bottom gate type thin film transistor lies in positions of the active layer and the gate electrode. Here, it is called a top gate type thin film transistor if the active layer is located below the gate electrode, and it is called a bottom gate type thin film transistor if the active layer is located above the gate electrode. At present, bottom gate type thin film transistor structures are used in most array substrates. This is because a metal gate electrode in a bottom gate type thin film transistor may be used as a protective layer of a semiconductor active layer to prevent electrical characteristics of the active layer from being impaired by photon-generated carriers which are generated due to the irradiation of light emitted from a back light source to an amorphous silicon layer. Therefore, description is made below by exemplifying a preparation method of a bottom gate type thin film transistor. However, this Example does not form a limitation to the preparation method, and the preparation method may also be used in the preparation of top gate type thin film transistors.

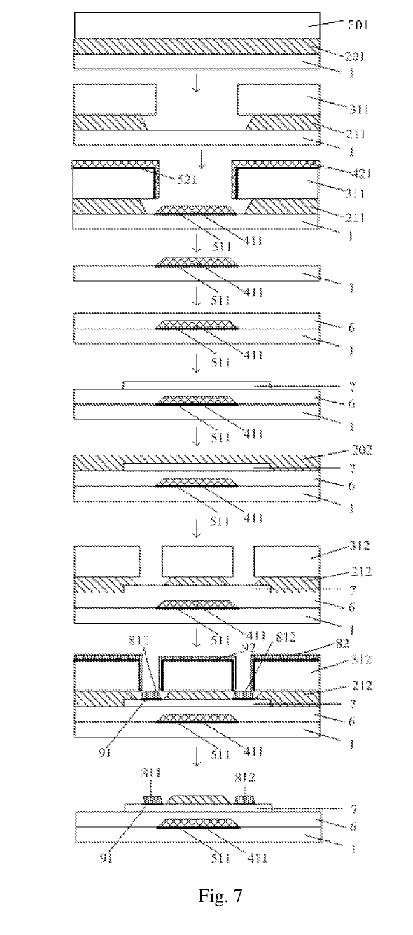

As shown in FIG. 7, the preparation method of a thin film transistor in this Example specifically comprises the following steps.

Step 1: a first sacrificial layer 201 and a first photoresist layer 301 are sequentially deposited on a substrate 1, and a patterned first sacrificial layer 211 and a patterned first photoresist layer 311 overlying on the patterned first sacrificial layer 211 are formed by exposure, development, and etching; wherein a side wall of the patterned first sacrificial layer 211 adjacent to a gate electrode to be formed forms a chamfer.

In this step, the substrate 1 is produced from transparent materials such as glass, etc., and is preliminarily cleaned. The first sacrificial layer 201 is formed on the substrate 1 in a manner of physical vapor deposition (PVD); the first photoresist layer is then coated in a manner of roller coating, and the patterned first sacrificial layer 211 and the patterned first photoresist layer 311 overlying on the patterned first sacrificial layer 211 are formed by exposure, development, and etching. Here, a side wall of the patterned first sacrificial layer 211 adjacent to a gate electrode to be formed forms a chamfer, which means that the sacrificial layer is allowed to be over-etched at the edge position.

Here, similarly to the sacrificial layer in Example 1, the first sacrificial layer 201 has a thickness higher than that of the gate metal film layer to be subsequently deposited, the material of the first sacrificial layer 201 is preferably aluminum oxide (Al₂O₃), and of course, another transparent insulating material may also be used as a bottom undercut processed patterned first sacrificial layer 211.

Here, the material of the first photoresist layer is preferably a positive photoresist. The reason thereof is the same with that of Example 1, and detailed description is omitted hereby.

Step 2: first adhesion layers 511 and 521 and gate metal film layers 411 and 421 are sequentially deposited on the substrate 1 after finishing the above step, and the patterned first sacrificial layer 211 and the patterned first photoresist layer 311 along with the gate metal film layer 421 thereon are removed to form a pattern of the patterned first adhesion layer 511 and the gate electrode 411.

Specifically, this step is to form first adhesion layers 511 and 521 and gate metal film layers 411 and 421 in a manner of physical vapor deposition (PVD) or magnetron sputtering. The thickness of the first sacrificial layer 211 is higher than that of the gate metal film layer 411 and special undercut treatment is performed on the patterned first sacrificial layer 211, such that the gate metal film layer 421 is disconnected from the gate metal film layer 411 at the bottom of the patterned first photoresist layer 311 after the gate metal film layer is deposited, and such that the photoresist-removing liquid may permeate from the boundary between the bottom of the patterned first photoresist layer 311 and the place where the patterned first sacrificial layer 211 is undercut. The patterned photoresist layer is removed with a photoresist-removing liquid, and thus the metal film layer on the photoresist layer is removed. Subsequently, an acid is used to remove the patterned first sacrificial layer, with only the patterned metal film layer left. Auxiliary means such ultrasonic treatment, oscillation, etc., may be added in the process of removing the patterned photoresist layer and the first sacrificial layer to increase the speed of the removing process and the effect of removing. The remaining gate metal film layer is a pattern of the gate electrode 411.

Here, the material of the gate metal film layer is preferably copper. A single layer or a stacked composite multilayer formed from one or more of molybdenum (Mo), molybdenum niobium alloy (MoNb), aluminum (Al), and aluminum neodymium alloy (AlNd) may also be used. The material of the first adhesion layer is preferably titanium.

Step 3, a gate electrode insulating layer 6 is formed on the substrate 1 after finishing the above step.

Particularly, in this step, the gate electrode insulating layer 6 is formed in a manner of thermal growth, plasma enhanced chemical vapor deposition (simply referred to as PECVD), low pressure chemical vapor deposition (simply referred to as LPCVD), atmospheric pressure chemical vapor deposition (simply referred to as APCVD), or electron cyclotron resonance chemical vapor deposition (simply referred to as ECR-CVD).

Here, the material of the gate electrode insulating layer 6 may be an oxide of silicon (SiOₓ), a nitride of silicon (SiNₓ), an oxide of hafnium (HfOₓ), an oxynitride of silicon (SiON), an oxide of aluminum (AlOₓ), etc., or is composed of several layers of films consisting of two or three of the above materials.

Step 4, a pattern of an active layer 7 is formed on the substrate 1 after finishing the above step.

In this step, an active layer thin film is deposited in a manner of plasma enhanced chemical vapor deposition and low pressure chemical vapor deposition, and a pattern comprising an active layer 7 (a-Si) is formed by a patterning process. Thereafter, a-Si is treated with a process such as laser annealing, etc., to form a p-Si structure, and procedures, such as selective p-type and n-type doping, etching, or the like, are performed to form a p-type doping channel area and a n-type doping source/drain contact area 006 for forming a NMOS structure with electrons as main part of carriers.

Here, the material of the active layer thin film may be an amorphous silicon film (a-Si) or a poly-silicon film (p-Si).

Step 5: a second sacrificial layer 202 and a second photoresist layer are sequentially deposited on the substrate 1 after finishing the above step, and a patterned second sacrificial layer 212 and a patterned second photoresist layer 312 overlying on the patterned second sacrificial layer 212 are formed by exposure, development, and etching; wherein a side wall of the patterned second sacrificial layer 212 (comprising two parts, in which one corresponds to a source electrode and the other one corresponds to a drain electrode) adjacent to a source electrode 811 and a drain electrode 812 to be formed forms a chamfer.

In this step, the substrate 1 after finishing the aforementioned step is preliminarily cleaned. The second sacrificial layer is formed on the substrate 1 in a manner of physical vapor deposition(PVD); the second photoresist layer is then coated in a manner of roller coating, and the patterned second sacrificial layer 212 and the patterned second photoresist layer 312 overlying on the patterned second sacrificial layer 212 are formed by exposure, development, and etching; wherein a side wall of the patterned second sacrificial layer 212 adjacent to a source electrode 811 and a drain electrode 812 to be formed forms a chamfer, which means that the sacrificial layer is allowed to be over-etched at the edge position.

Step 6, a second adhesion layer and a source and drain metal layer are sequentially deposited on the substrate 1 after finishing the above step to form a pattern comprising a patterned second adhesion layer 91, a source electrode 811, and a drain electrode 812.

In this step, a second adhesion layer 92 and a source and drain metal film layer 82 are formed in a manner of physical vapor deposition (PVD) or magnetron sputtering. The upper surface of the second sacrificial layer 202 is higher than the source and drain metal film layer 82, and special undercut treatment is performed on the patterned second sacrificial layer 212, such that the source and drain metal film layer is disconnected from the source and drain metal film layers 811 and 812 at the bottom of the patterned photoresist layer after the source and drain metal film layer is deposited, and such that the photoresist-removing liquid may permeate from the boundary between the bottom of the patterned second photoresist layer 312 and the place where the patterned second sacrificial layer 212 is undercut. The patterned photoresist layer is removed with a photoresist-removing liquid, and thus the metal film layer on the photoresist layer is removed. Subsequently, an acid is used to remove the patterned second sacrificial layer, with only the patterned metal film layer left. Auxiliary means such ultrasonic treatment, oscillation, etc., may be added in the process of removing the patterned photoresist layer and the second sacrificial layer, to increase the speed of the removing process and the effect of removing. The remaining source and drain metal film layer is a pattern of the source electrode 811 and the drain electrode 812.

By far, the preparation of the thin film transistor is achieved.

### EXAMPLE 3

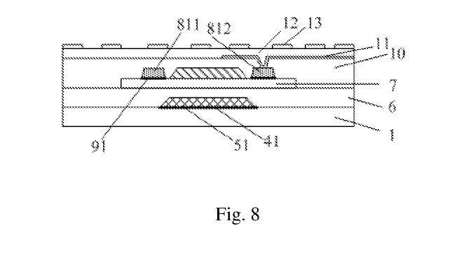

As shown in FIG. 8, this Example provides a preparation method of an array substrate, comprising the steps of preparing the thin film transistor in Example 2, and further comprising:

a step of forming a passivation layer 10 on the substrate 1 after forming the thin film transistor; thereafter, a through hole corresponding to the position of the drain electrode 812 is formed in the passivation layer 10; a pattern comprising a pixel electrode 11 is formed by a patterning process after the through hole is formed, wherein the pixel electrode 11 is connected to the drain electrode 812 by the through hole. A planarizing layer 12 is formed on the substrate 1 having the pixel electrode 11 formed thereon, and then a pattern of a common electrode 13 is formed on the substrate 1 formed with the planarizing layer 12.

It can be understood that the above embodiments are merely exemplary embodiments used for illustrating the principle of the invention. However, the invention is not limited thereto. With respect to those of ordinary skill in the art, various variations and modifications can be made without departing from the spirit and the substance of the invention. These variations and modifications are also considered as the scope protected by the invention.

What is claimed is:

1. A method of forming a patterned metal film layer, comprising:
sequentially depositing a sacrificial layer and a photoresist layer on a substrate, and forming a patterned sacrificial layer and a patterned photoresist layer overlying on the patterned sacrificial layer by exposure, development, and etching, wherein a side wall of the patterned sacrificial layer adjacent to a patterned metal film layer to be formed forms a chamfer;
depositing a metal film layer on the substrate after finishing sequentially depositing the sacrificial layer and a photoresist layer on the substrate and forming the patterned sacrificial layer and the patterned photoresist layer overlying on the patterned sacrificial layer, wherein an upper surface of the sacrificial layer is higher than an upper surface of the patterned metal film layer to be formed; and
removing the patterned photoresist layer and the sacrificial layer to form the patterned metal film layer.

2. The method of forming a patterned metal film layer according to claim 1, wherein before depositing the metal film layer, the method further comprises:
depositing an adhesion layer.

3. The method of forming a patterned metal film layer according to claim 2, wherein the adhesion layer is composed of titanium.

4. The method of forming a patterned metal film layer according to claim 1, wherein the sacrificial layer is composed of aluminum oxide.

5. The method of forming a patterned metal film layer according to claim 1, wherein the metal film layer is composed of copper.

6. The method of forming a patterned metal film layer according to claim 1, wherein the photoresist layer is composed of a positive photoresist.

7. The method of forming a patterned metal film layer according to claim 1, wherein removing the patterned photoresist layer and the sacrificial layer to form the patterned metal film layer specifically comprises:
removing the patterned photoresist layer with a photoresist-removing liquid, thereby removing the metal film layer on the photoresist layer; and
removing the patterned sacrificial layer with acid to form the patterned metal film layer, wherein the acid does not corrode the substrate and the metal film layer.

8. The method of forming a patterned metal film layer according to claim 7, wherein the acid is phosphoric acid or hydrochloric acid.

9. The method of forming a patterned metal film layer according to claim 7, wherein ultrasonic treatment and oscillation are used as auxiliary means in the process of removing the patterned photoresist layer and the sacrificial layer.

10. A preparation method of a thin film transistor comprising a gate electrode, a source electrode, and a drain electrode, wherein the gate electrode and/or the source electrode and drain electrode are produced by using the method of forming a patterned metal film layer of claim 1.

11. A preparation method of an array substrate, wherein the preparation method comprises the preparation method of a thin film transistor of claim 10.
